(19) United States
(12) Patent Application Publication
(10) Pub. No.: US 2025/0130309 A1
(43) Pub. Date: Apr. 24, 2025

(54) REMOTE SENSING OBSERVATION EQUIPMENT AND METHOD

(71) Applicants: Chongqing Academy of Ecology and Environment Sciences, Chongqing (CN); Chongqing Institute of Green and Intelligent Technology, Chinese Academy of Sciences, Chongqing (CN); Zhongke Yaoguang (Chongqing) Intelligent Technology Co., Ltd., Chongqing (CN); Chongqing Pulus Environmental Protection Technology Development Co., Ltd., Chongqing (CN)

(72) Inventors: Li FENG, Chongqing (CN); Lei FENG, Chongqing (CN); Weiling LIAO, Chongqing (CN); Jinkun XU, Chongqing (CN); Menglan GAN, Chongqing (CN); Yao WANG, Chongqing (CN); Jiawei PANG, Chongqing (CN); Xiaohu YU, Chongqing (CN); Botian ZHOU, Chongqing (CN); Boxun CHEN, Chongqing (CN); Jun MOU, Chongqing (CN)

(73) Assignees: Chongqing Academy of Ecology and Environment Sciences, Chongqing (CN); Chongqing Institute of Green and Intelligent Technology, Chinese Academy of Sciences, Chongqing (CN); Zhongke Yaoguang (Chongqing) Intelligent Technology Co., Ltd., Chongqing (CN); Chongqing Pulus Environmental Protection Technology Development Co., Ltd., Chongqing (CN)

(21) Appl. No.: 18/918,004

(22) Filed: Oct. 16, 2024

(30) Foreign Application Priority Data
Oct. 19, 2023 (CN) 202311354476.0

(51) Int. Cl. G01S 7/02

(52) U.S. Cl. CPC G01S 7/027

(57) ABSTRACT

The provided is a remote sensing observation equipment, including a base and a remote sensing observation instrument, the remote sensing observation instrument is located above the base, a lifting mechanism is arranged between the remote sensing observation instrument and the base, a sliding groove is arranged on both sides of the middle part of the base, both of the sliding grooves are slidingly assembled with sliding seats, both of the sliding seats are fixed with a first protective shell, the ends of the two first protective shells are abut against each other and located outside the remote sensing observation instrument, a fixed mechanism is arranged between the sliding seat and the sliding groove; protecting the remote sensing observation instrument through the first protective shell and the second protective shell being closed to each other, avoids the instrument being damaged by collision, and prolongs the service life of the instrument.

### CROSS-REFERENCE TO THE RELATED APPLICATIONS

This application is based upon and claims priority to Chinese Patent Application No. 202311354476.0, filed on Oct. 19, 2023, the entire contents of which are incorporated herein by reference.

### TECHNICAL FIELD

The present invention belongs to the field of remote sensing observation technology, and specifically relates to a remote sensing observation equipment and a method.

### BACKGROUND

Remote sensing refers to a detection technology with non-contact and long-distance, nowadays, when carrying out a ground positioning experiment, it is usually necessary to use observation equipment to observe and monitor the objects and types that need to be observed.

After retrieval, the patent document with authorization publication number CN206580500U has disclosed a ground agricultural remote sensing observation equipment, which involves the technical field of agricultural appliances; the bottom of a base is mounted with a self-locking roller, the upper end of the base is mounted with an adjusting thread sleeve, the adjusting screw is arranged in the adjusting thread sleeve, the adjusting screw is connected to the adjusting thread sleeve in a locked manner through a locking nut, the upper end of the adjusting screw is mounted with a support plate, both ends of the bottom of the support plate are mounted with a twist handle, the inner part of the support plate is mounted with a bearing seat, the inner part of the bearing seat is mounted with a shaft, the upper end of the shaft is mounted with an installation plate, both ends of the installation plate are mounted with a wind disk, both sides of the bottom of the installation plate are mounted with a supporting ball mechanism, and the middle part of the installation plate is mounted with a remote sensing observation equipment body, both ends of the adjusting thread sleeve are mounted with a counterweight frame, and several counterweight partition plates are arranged inside the counterweight frame.

Although the above existing technical solutions can realize adjustment and observation, there is a lack of a protective device for a remote sensing observation instrument, the remote sensing observation instrument is vulnerable to collision and damage when the equipment is not used.

### SUMMARY

An objective of the present invention is to provide a remote sensing observation equipment and a method for solving the problems raised in the background technology.

In order to achieve the above technical objective, the technical scheme adopted by the present invention is as follows:
a remote sensing observation equipment, comprising a base and a remote sensing observation instrument, the remote sensing observation instrument is located above the base, a lifting mechanism is arranged between the remote sensing observation instrument and the base, a sliding groove is arranged on both sides of the middle part of the base, both of the sliding grooves are slidingly assembled with sliding seats, both of the sliding seats are fixed with a first protective shell, the ends of the two first protective shells are abutted against each other and located outside the remote sensing observation instrument, a fixed mechanism is arranged between the sliding seat and the sliding groove;
a movable groove is arranged on the upper side of the two first protective shells, and a second protective shell is slidingly assembled in the movable groove, a vertical groove is arranged on the inner side of the first protective shell, the second protective shell is fixed with a guide block that runs through the vertical groove, the upper side of the base is fixed with a guide rail that matches the guide block, the guide rail is composed of a transverse sliding rail and an oblique sliding rail, the transverse sliding rail is horizontally arranged on the upper side of the base, the oblique sliding rail is connected to the end of the transverse sliding rail, and the guide block is located at the end of the transverse sliding rail.

The lifting mechanism comprises a rectangular shell that fixed in the middle part of the base, a screw is rotatably assembled in the rectangular shell, the rectangular shell is slidingly assembled with a rectangular sliding plate that connected to a screw in a threaded manner, the upper side of the rectangular sliding plate is connected to a support rod, the upper end of the support rod runs through the rectangular shell and is connected to the remote sensing observation instrument, the bottom of the screw is fixed with a first helical tooth, the front side of the bottom of the rectangular shell is rotatably assembled with a second helical tooth that meshes with the first helical tooth, the front side of the second helical tooth is connected to a handle.

The side wall of the first protective shell is fixed with an L-shaped handle.

The fixed mechanism comprises a chamber that arranged in the middle part of the sliding seat, the chamber is slidingly assembled with a movable plate, the front and rear ends of the movable plate are hinged with hinged rods, the front and rear sides of the chamber are provided with sliding grooves, the two sliding grooves are slidingly assembled with lock rods, the two hinged rods are hinged with the two lock rods respectively, the left and right sides of the sliding groove are provided with two sets of lock grooves that match the lock rods, a spring is arranged between the movable plate and the side wall of the chamber, the movable plate is connected to a tie rod, the tie rod slides out of the sliding seat and is connected to a pull rod.

The upper end of the pull rod is located the inside of the L-shaped handle.

The two second protective shells are provided with sealing strips on the opposite side.

The two front and rear sides of the first protective shell are rotatably assembled with a circular base, the lower end of the circular base is mounted with a universal wheel, the upper end of the circular base is fixed with a ground nail, and the circular base is provided with a rotary assembly.

The rotary assembly comprises a strip groove that arranged on the base, a rectangular block is slidingly assembled in the strip groove, the rectangular block is rotatably assembled with a rotary rod, the end of the rotary rod is fixedly connected to the circular base, the upper wall of the end of the strip groove is fixed with a positioning block, and the rotary rod is provided with a rotary groove that matches with the positioning block, the rotary groove is composed of two transverse grooves and a spiral groove, the two transverse grooves are located on the left and right sides of the rotary rod and distributed up and down, and the two ends of the spiral groove are in communication with the two transverse grooves.

The present invention protects the remote sensing observation instrument through the first protective shell and the second protective shell being closed to each other, avoids the instrument from being damaged by collision, and prolongs the service life of the instrument, the second protective shell can be automatically put into the movable groove when the first protective shell is arranged, which will not block the remote sensing observation instrument and is simple to use.

### BRIEF DESCRIPTION OF THE DRAWINGS

The present invention can be further explained by the non-restricted embodiment given in the attached drawings.

FIG. 1 is a structural schematic diagram 1 of the embodiment of a remote sensing observation equipment of the present invention;

FIG. 2 is a schematic diagram of a profile structure of the embodiment of a remote sensing observation equipment of the present invention;

FIG. 3 is a schematic diagram 1 of an internal structure of the embodiment of a remote sensing observation equipment of the present invention;

FIG. 4 is a structure enlargement diagram at A in FIG. 3;

FIG. 5 is a structure diagram of a first protective shell and a second protective shell of the present invention;

FIG. 6 is a structure enlargement diagram at B in FIG. 5;

FIG. 7 is a schematic diagram of a profile structure of a base of the present invention;

FIG. 8 is a structure enlargement diagram at C in FIG. 7;

FIG. 9 is a schematic diagram 2 of the internal structure of the embodiment of a remote sensing observation equipment of the present invention;

FIG. 10 is a structural schematic diagram 2 of the embodiment of a remote sensing observation equipment of the present invention;

the main component symbols are described as follows:
a base 1; a sliding groove 11; a sliding seat 12; a first protective shell 13; an L-shaped handle 130; a vertical groove 131; a guide block 132; a transverse sliding rail 133; an oblique sliding rail 134; a second protective shell 14; a remote sensing observation instrument 2; a rectangular shell 21; a screw 22; a rectangular sliding plate 23; a support rod 24; a first helical tooth 25; a second helical tooth 26; a handle 27; a chamber 3; a movable plate 31; a hinged rod 32; a lock rod 33; a lock groove 34; a spring 35; a tie rod 36; a pull rod 37; a circular base 4; a universal wheel 41; a ground nail 42; a strip groove 43; a rectangular block 44; a rotary rod 45; a transverse groove 451; a spiral groove 452; a positioning block 46.

### DETAILED DESCRIPTION OF THE EMBODIMENTS

In order to enable technicians in this field to better understand the present invention, the technical scheme of the present invention is further explained in combination with the attached drawings and embodiments.

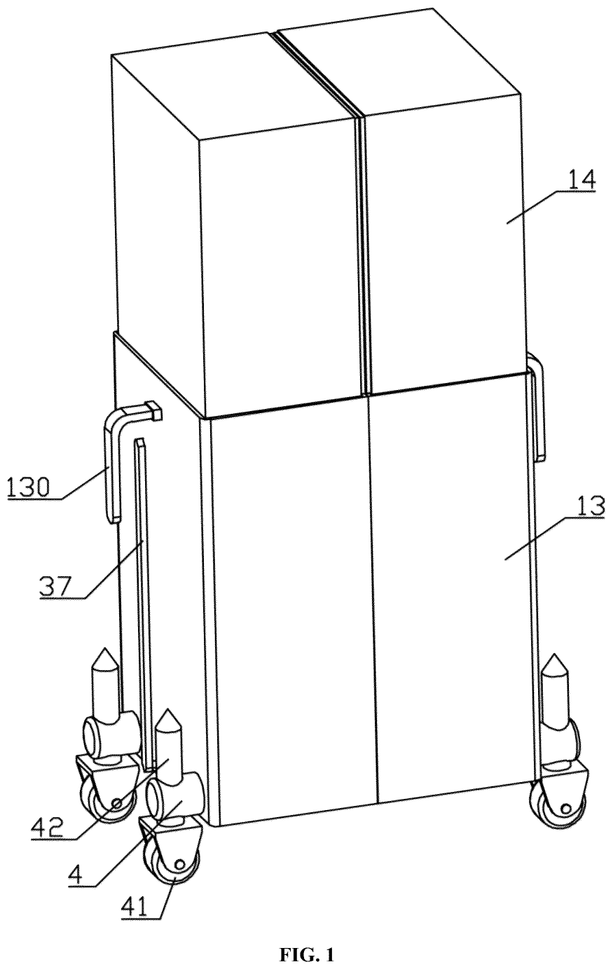

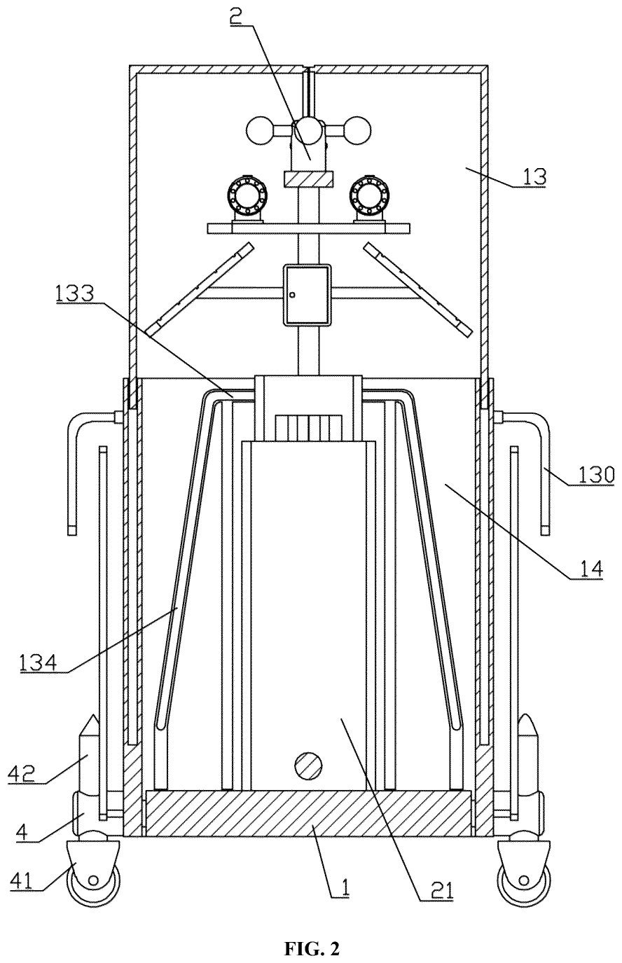

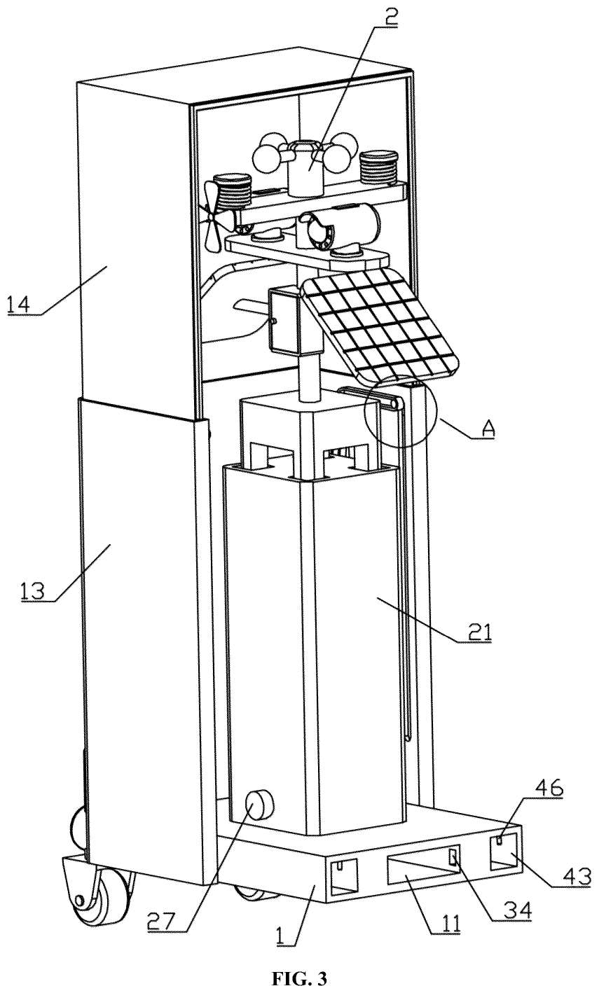

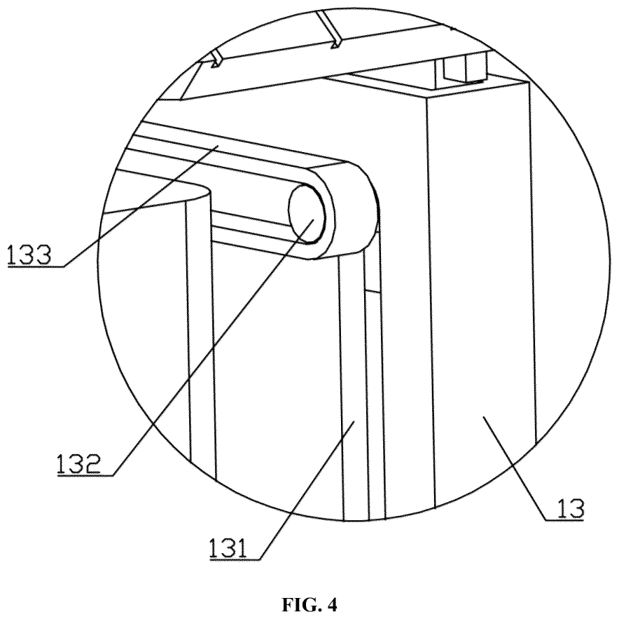

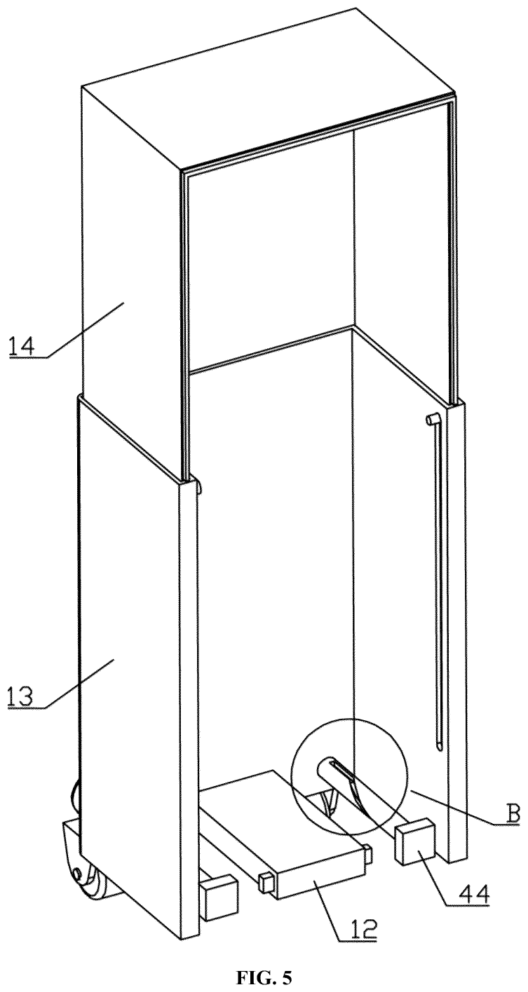

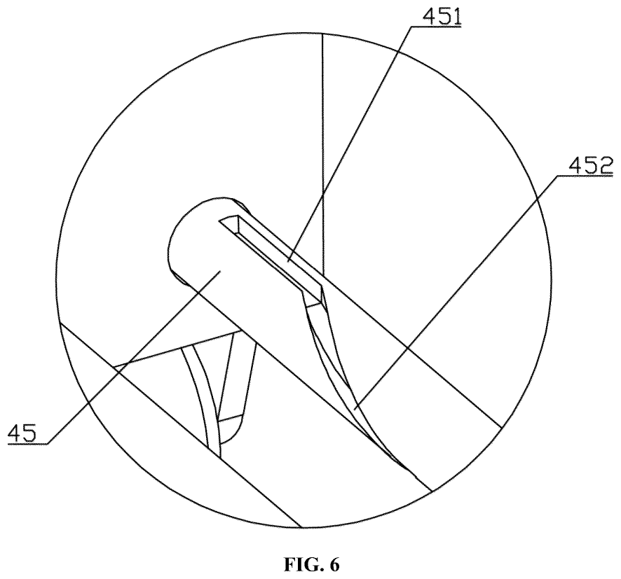

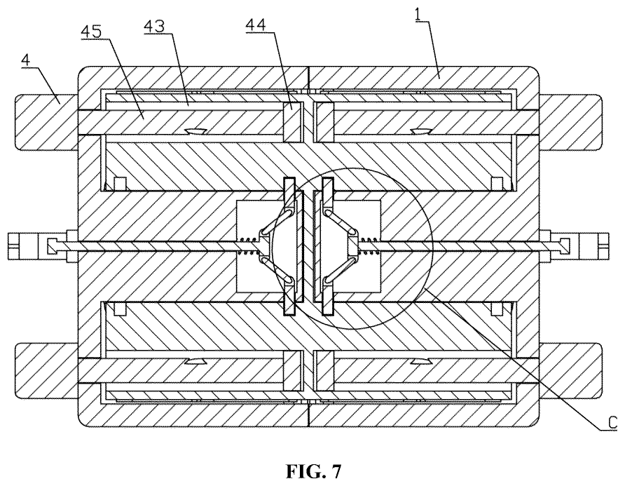

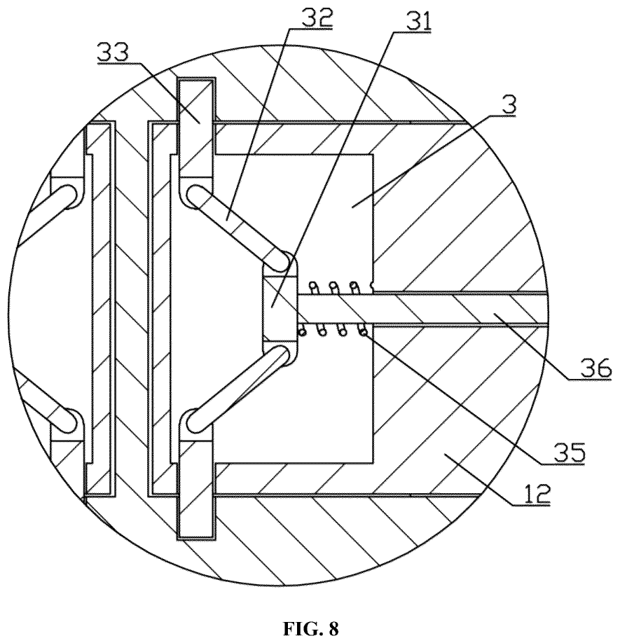

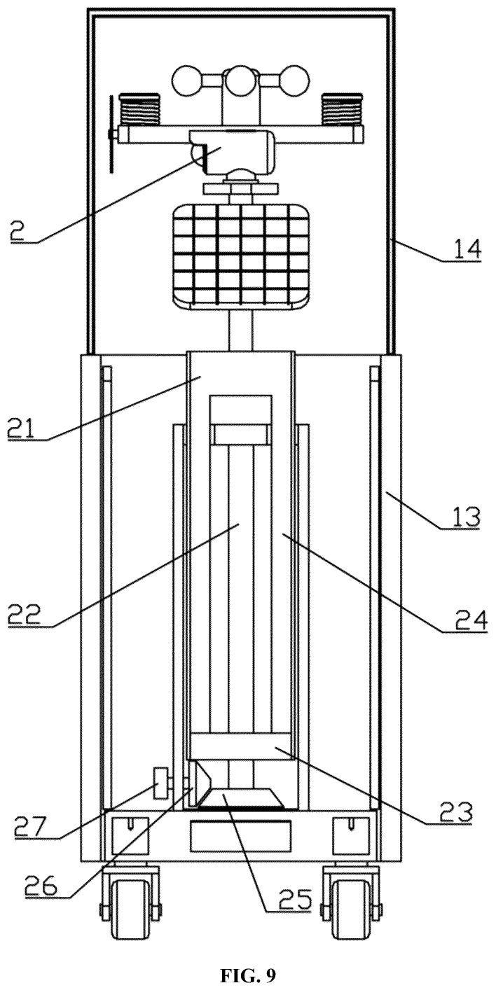

As shown in FIGS. 1-10, a remote sensing observation equipment of the present invention, comprising a base 1 and a remote sensing observation instrument 2, the remote sensing observation instrument 2 is located above the base 1, a lifting mechanism is arranged between the remote sensing observation instrument 2 and the base 1, a sliding groove 11 is arranged on both sides of the middle part of the base 1, both of the sliding grooves 11 are slidingly assembled with sliding seats 12, both of the sliding seats 12 are fixed with a first protective shell 13, the ends of the two first protective shells 13 are abutted against each other and located outside the remote sensing observation instrument 2, a fixed mechanism is arranged between the sliding seat 12 and the sliding groove 11;
a movable groove is arranged on the upper side of the two first protective shells 13, and a second protective shell 14 is slidingly assembled in the movable groove, a vertical groove 131 is arranged on the inner side of the first protective shell 13, the second protective shell 14 is fixed with a guide block 132 that runs through the vertical groove 131, the upper side of the base 1 is fixed with a guide rail that matches the guide block 132, the guide rail is composed of a transverse sliding rail 133 and an oblique sliding rail 134, the transverse sliding rail 133 is horizontally arranged on the upper side of the base 1, the oblique sliding rail 134 is connected to the end of the transverse sliding rail 133, and the guide block 132 is located at the end of the transverse sliding rail 133.

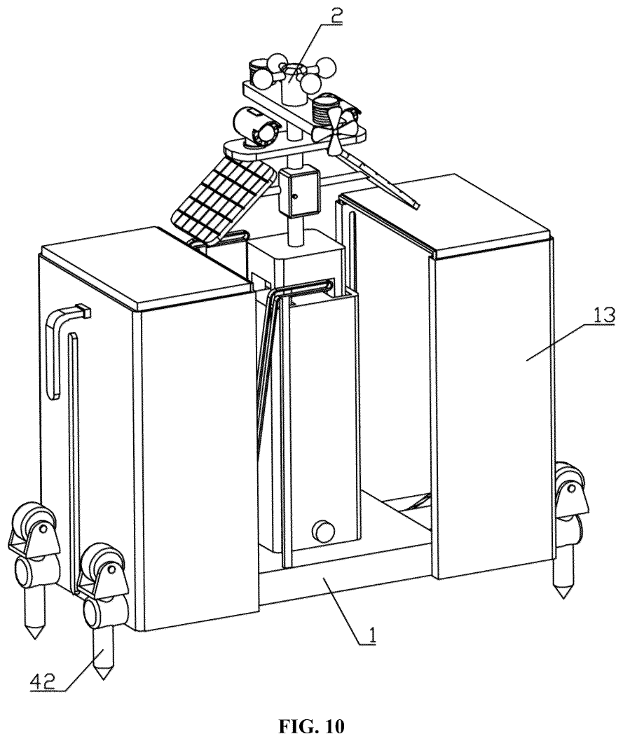

In the unused state of the equipment, the two second protective shells 14 extend the movable groove of the first protective shell 13, at this time, the ends of the two first protective shells 13 and the two second protective shells 14 are abutted against each other, and the remote sensing observation instrument 2 is completely wrapped, so that the equipment can fully protect the remote sensing observation instrument 2 when not in use, avoid the instrument being damaged by collision, and prolong the service life of the instrument;
after the device is moved to a specified position, the fixed mechanism between the sliding seat 12 and the sliding groove 11 is released, and the staff slides the two first protective shells 13 on both sides to drive the two first protective shells 13 away from each other, the first protective shell 13 will drive the second protective shell 14 to move synchronously, the guide block 132 which is connected with the second protective shell 14 will slide horizontally along the transverse sliding rail 133, when the two first protective shells 13 are far away from each other for a certain distance, the guide block 132 will leave the transverse sliding rail 133 and enter the oblique sliding rail 134, therefore, when the first protective shell 13 continues to move, the second protective shell 14 will gradually move downward and put into to the inside of the movable groove, therefore, when the two first protective shells 13 are completely away from the remote sensing observation instrument 2, the second protective shell 14 will be put into the movable groove of the first protective shell 13, as shown in FIG. 10, which will not be located on both sides of the remote sensing observation instrument 2, that is, it will not block the remote sensing observation instrument 2;
the present invention protects the remote sensing observation instrument through the first protective shell and the second protective shell being closed to each other, avoids the instrument from being damaged by collision, and prolongs the service life of the instrument, the second protective shell can be automatically put into the movable groove when the first protective shell is arranged, which will not block the remote sensing observation instrument and is simple to use.

The lifting mechanism comprises a rectangular shell 21 that fixed in the middle part of the base 1, a screw 22 is rotatably assembled in the rectangular shell 21, the rectangular shell 21 is slidingly assembled with a rectangular sliding plate 23 that connected to a screw 22 in a threaded manner, the upper side of the rectangular sliding plate 23 is connected to a support rod 24, the upper end of the support rod 24 runs through the rectangular shell 21 and is connected to the remote sensing observation instrument 2, the bottom of the screw 22 is fixed with a first helical tooth 25, the front side of the bottom of the rectangular shell 21 is rotatably assembled with a second helical tooth 26 that meshes with the first helical tooth 25, the front side of the second helical tooth 26 is connected to a handle 27;
when the remote sensing observation instrument 2 is operating, its height can be adjusted by the lifting mechanism, that is, the staff rotates the handle 27 to drive the second helical tooth 26 to rotate, thereby driving the screw 22 to rotate through the first helical tooth 25, because the rectangular sliding plate 23 sliding in the rectangular shell 21 is connected to the screw 22 in a threaded manner, the rotation of the screw 22 can drive the rectangular sliding plate 23 to slide upward, the support rod 24 drives the remote sensing observation instrument 2 to move upward, and the direction rotation makes the handle 27 to drive the screw 22 to rotate reversely, which can drive the remote sensing observation instrument 2 to move downward and realize the height adjustment of the remote sensing observation instrument 2.

The side wall of the first protective shell 13 is fixed with an L-shaped handle 130; it is convenient for the staff to operate the first protective shell 13 by setting the L-shaped handle 130.

The fixed mechanism comprises a chamber 3 that arranged in the middle part of the sliding seat 12, the chamber 3 is slidingly assembled with a movable plate 31, the front and rear ends of the movable plate 31 are hinged with hinged rods 32, the front and rear sides of the chamber 3 are provided with sliding grooves, the two sliding grooves are slidingly assembled with lock rods 33, the two hinged rods 32 are hinged with the two lock rods 33 respectively, the left and right sides of the sliding groove 11 are provided with two sets of lock grooves 34 that match the lock rods 33, a spring 35 is arranged between the movable plate 31 and the side wall of the chamber 3, the movable plate 31 is connected to a tie rod 36, the tie rod 36 slides out of the sliding seat 12 and is connected to a pull rod 37;
the upper end of the pull rod 37 is located the inside of the L-shaped handle 130;
when the two first protective shells 13 are closed to each other, the lock rod 33 is located in the lock groove 34 near the middle part of the base 1, when the two first protective shells 13 are separated, while holding the L-shaped handle 130, the staff pulls the pull rod 37 outward with their fingers, drives the movable plate 31 to move through the tie rod 36, the movable plate 31 pulls the two lock rods 33 close with each other through the hinge rod 32, that is, the lock rod 33 exits the lock groove 34, the fixation between the sliding seat 12 and the sliding groove 11 is released, then the staff can pull the first protective shell 13 to both sides until the two first protective shells 13 are far away from each other, and after the lock rod 33 is aligned with the lock groove 34 that away from the middle part of the base 1, the staff loosened the pull rod 37, and pushed the movable plate 31 to reset through the elastic force of the spring 35, that is, the hinge rod 32 drives the two lock rods 33 into the lock groove 34 for fixation;
therefore, the staff can easily release the fixation between the sliding seat 12 and the sliding groove 11, thus driving the two protective shells 13 to move, which is convenient to operate and easy to use in practice.

The two second protective shells 14 are provided with sealing strips on the opposite side; when the two second protective shells 14 are closed to each other, it can increase the sealing and improve the protection effect.

The two front and rear sides of the first protective shell 13 are rotatably assembled with a circular base 4, the lower end of the circular base 4 is mounted with a universal wheel 41, the upper end of the circular base 4 is fixed with a ground nail 42, and the circular base 4 is provided with a rotary assembly;
the rotary assembly comprises a strip groove 43 that arranged on the base 1, a rectangular block 44 is slidingly assembled in the strip groove 43, the rectangular block 43 is rotatably assembled with a rotary rod 45, the end of the rotary rod 445 is fixedly connected to the circular base 4, the upper wall of the end of the strip groove 43 is fixed with a positioning block 46, and the rotary rod 45 is provided with a rotary groove that matches with the positioning block 46, the rotary groove is composed of two transverse grooves 451 and a spiral groove 452, the two transverse grooves 451 are located on the left and right sides of the rotary rod 45 and distributed up and down, and the two ends of the spiral groove 453 are in communication with the two transverse grooves 451;
when the two first protective shells 13 are close to each other, the universal wheel 41 is located at the lower end of the circular base 4, at this time, the whole equipment is supported by four universal wheels 41, therefore, it can be moved by the universal wheel 41 without manual moving device when the device is not used;
when the equipment moves to the specified position, two staff stand on both sides of the equipment, holding the L-shaped handle 130 while pulling the pull rod 37 outward, releasing the fixation of the sliding seat 12 and the sliding groove 11, and raising the equipment upward for a certain distance, and then pulling the two first protective shells 13 away from each other, the first protective shell 13 will drive the rectangular block 44 to slide outward in the strip groove 43 through the rotary rod 45, while the positioning block 46 is located in the transverse groove 451, until the spiral groove 453 moves to the lower part of the positioning block 46, the positioning block 46 enters the spiral groove 453, which will drive the rotary rod 45 to rotate, thereby driving the circular base 4 to rotate, the universal wheel 41 gradually rotates upwards, and the ground nail 42 will rotate downwards, after the positioning block 46 enters another transverse groove 451, the ground nail 42 will directed downwards;
finally, the staff will put down the equipment, the ground nail will be inserted into the ground, and the bottom of the base 1 will also be released from the ground, so when the two first protective shells 13 are opened, the ground nail can be automatically directed downward, so that the equipment can be fixed by inserting the ground nail into the ground, and the equipment is more stable and less prone to offset.

The above-described embodiments merely illustrate the principle of the present invention and its efficacy, and are not used to restrict the present invention. Anyone familiar with this technology can modify or change the above embodiments without violating the spirit and scope of the present invention. Therefore, all equivalent modifications or changes made in the technical field by a person who has general knowledge without breaking away from the spirit and technical ideas revealed by the present invention shall still be covered by the claims of the present invention.

What is claimed is:

1. A remote sensing observation equipment, comprising a base and a remote sensing observation instrument, the remote sensing observation instrument is located above the base, a lifting mechanism is arranged between the remote sensing observation instrument and the base, a sliding groove is arranged on both sides of a middle part of the base, both of the sliding grooves are slidingly assembled with sliding seats, both of the sliding seats are fixed with a first protective shell, ends of the two first protective shells are abutted against each other and located outside the remote sensing observation instrument, a fixed mechanism is arranged between the sliding seat and the sliding groove;
a movable groove is arranged on an upper side of the two first protective shells, and a second protective shell is slidingly assembled in the movable groove, a vertical groove is arranged on an inner side of the first protective shell, the second protective shell is fixed with a guide block, wherein the guide block runs through the vertical groove, an upper side of the base is fixed with a guide rail, wherein the guide rail matches the guide block, the guide rail is composed of a transverse sliding rail and an oblique sliding rail, the transverse sliding rail is horizontally arranged on the upper side of the base, the oblique sliding rail is connected to an end of the transverse sliding rail, and the guide block is located at the end of the transverse sliding rail.

2. The remote sensing observation equipment according to claim 1, wherein the lifting mechanism comprises a rectangular shell, wherein the rectangular shell is fixed in the middle part of the base, a screw is rotatably assembled in the rectangular shell, the rectangular shell is slidingly assembled with a rectangular sliding plate, wherein the rectangular sliding plate is connected to a screw in a threaded manner, an upper side of the rectangular sliding plate is connected to a support rod, an upper end of the support rod runs through the rectangular shell and is connected to the remote sensing observation instrument, a bottom of the screw is fixed with a first helical tooth, a front side of a bottom of the rectangular shell is rotatably assembled with a second helical tooth, wherein the second helical tooth meshes with the first helical tooth, a front side of the second helical tooth is connected to a handle.

3. The remote sensing observation equipment according to claim 1, wherein a side wall of the first protective shell is fixed with an L-shaped handle.

4. The remote sensing observation equipment according to claim 3, wherein the fixed mechanism comprises a chamber, wherein the chamber is arranged in a middle part of the sliding seat, the chamber is slidingly assembled with a movable plate, front and rear ends of the movable plate are hinged with hinged rods, front and rear sides of the chamber are provided with sliding grooves, the two sliding grooves are slidingly assembled with lock rods, the two hinged rods are hinged with the two lock rods, respectively, left and right sides of the sliding groove are provided with two sets of lock grooves, wherein the two sets of lock grooves match the lock rods, a spring is arranged between the movable plate and a side wall of the chamber, the movable plate is connected to a tie rod, the tie rod slides out of the sliding seat and is connected to a pull rod.

5. The remote sensing observation equipment according to claim 4, wherein an upper end of the pull rod is located an inside of the L-shaped handle.

6. The remote sensing observation equipment according to claim 1, wherein the two second protective shells are provided with sealing strips on an opposite side.

7. The remote sensing observation equipment according to claim 1, wherein two front and rear sides of the first protective shell are rotatably assembled with a circular base, a lower end of the circular base is mounted with a universal wheel, an upper end of the circular base is fixed with a ground nail, and the circular base is provided with a rotary assembly.

8. The remote sensing observation equipment according to claim 7, wherein the rotary assembly comprises a strip groove, wherein the strip groove is arranged on the base, a rectangular block is slidingly assembled in the strip groove, the rectangular block is rotatably assembled with a rotary rod, an end of the rotary rod is fixedly connected to the circular base, an upper wall of an end of the strip groove is fixed with a positioning block, and the rotary rod is provided with a rotary groove, wherein the rotary groove matches with the positioning block, the rotary groove is composed of two transverse grooves and a spiral groove, the two transverse grooves are located on left and right sides of the rotary rod and distributed up and down, and two ends of the spiral groove are in communication with the two transverse grooves.

9. A using method for the remote sensing observation equipment according to claim 1, comprising the following steps:
S1: protecting the remote sensing observation instrument through a cooperation of the first protective shell and the second protective shell;
S2: the remote sensing observation equipment is allowed to be moved through four universal wheels to move the remote sensing observation equipment to a specified position;
S3: after moving the remote sensing observation equipment to the specified position, staff lifts the remote sensing observation equipment, and pulls the two first protective shells away from each other; when the two first protective shells are away from each other, the second protective shell is allowed to be automatically put into the movable groove; at the same time, a circular base will rotate, and a ground nail will directed downwards, and the remote sensing observation equipment is allowed to be fixed on ground through the ground nail to increase a stability of the remote sensing observation equipment.

10. The using method according to claim 9, wherein in the remote sensing observation equipment, the lifting mechanism comprises a rectangular shell, wherein the rectangular shell is fixed in the middle part of the base, a screw is rotatably assembled in the rectangular shell, the rectangular shell is slidingly assembled with a rectangular sliding plate, wherein the rectangular sliding plate is connected to a screw in a threaded manner, an upper side of the rectangular sliding plate is connected to a support rod, an upper end of the support rod runs through the rectangular shell and is connected to the remote sensing observation instrument, a bottom of the screw is fixed with a first helical tooth, a front side of a bottom of the rectangular shell is rotatably assembled with a second helical tooth, wherein the second helical tooth meshes with the first helical tooth, a front side of the second helical tooth is connected to a handle.

11. The using method according to claim 9, wherein in the remote sensing observation equipment, a side wall of the first protective shell is fixed with an L-shaped handle.

12. The using method according to claim 11, wherein in the remote sensing observation equipment, the fixed mechanism comprises a chamber, wherein the chamber is arranged in a middle part of the sliding seat, the chamber is slidingly assembled with a movable plate, front and rear ends of the movable plate are hinged with hinged rods, front and rear sides of the chamber are provided with sliding grooves, the two sliding grooves are slidingly assembled with lock rods, the two hinged rods are hinged with the two lock rods, respectively, left and right sides of the sliding groove are provided with two sets of lock grooves, wherein the two sets of lock grooves match the lock rods, a spring is arranged between the movable plate and a side wall of the chamber, the movable plate is connected to a tie rod, the tie rod slides out of the sliding seat and is connected to a pull rod.

13. The using method according to claim 12, wherein in the remote sensing observation equipment, an upper end of the pull rod is located an inside of the L-shaped handle.

14. The using method according to claim 9, wherein in the remote sensing observation equipment, the two second protective shells are provided with sealing strips on an opposite side.

15. The using method according to claim 9, wherein in the remote sensing observation equipment, two front and rear sides of the first protective shell are rotatably assembled with the circular base, a lower end of the circular base is mounted with a universal wheel, an upper end of the circular base is fixed with the ground nail, and the circular base is provided with a rotary assembly.

16. The using method according to claim 15, wherein in the remote sensing observation equipment, the rotary assembly comprises a strip groove, wherein the strip groove is arranged on the base, a rectangular block is slidingly assembled in the strip groove, the rectangular block is rotatably assembled with a rotary rod, an end of the rotary rod is fixedly connected to the circular base, an upper wall of an end of the strip groove is fixed with a positioning block, and the rotary rod is provided with a rotary groove, wherein the rotary groove matches with the positioning block, the rotary groove is composed of two transverse grooves and a spiral groove, the two transverse grooves are located on left and right sides of the rotary rod and distributed up and down, and two ends of the spiral groove are in communication with the two transverse grooves.
